(19) United States
(12) Patent Application Publication
(10) Pub. No.: US 2006/0040460 A1
(43) Pub. Date: Feb. 23, 2006

(54) MIS capacitor and production method of MIS capacitor

(75) Inventors: Yasushi Kakimura, Kawasaki (JP); Keisuke Muraya, Kawasaki (JP)

Correspondence Address: STAAS & HALSEY LLP, SUITE 700, 1201 NEW YORK AVENUE, N.W., WASHINGTON, DC, 20005, US

(73) Assignee: Fujitsu Limited, Kawasaki (JP)

(21) Appl. No.: 11/057,837

(22) Filed: Feb. 15, 2005

(30) Foreign Application Priority Data
Aug. 19, 2004 (JP) 2004-238975

(51) Int. Cl. H01L 21/20; H01L 21/8242

(52) U.S. Cl. 438/394; 438/393; 438/251; 438/250

(57) ABSTRACT

Silicon wafer, with diffusion area formed in a predetermined area of one side, consists of the lower electrode of capacitor. The first metal layer is connected to the first power supply wiring VDD and consists of the upper electrode of capacitor. The second metal layers are connected to the second power supply wiring GND and are formed on the side where diffusion area is formed on silicon wafer. Oxide film is placed between the first metal layer and the surface of silicon wafer where the diffusion area is formed.

### BACKGROUND OF THE INVENTION

1. Field of the Invention

The present invention relates to MIS (Metal-Insulator-Silicon) capacitor and a production method of MIS capacitor

2. Description of the Related Art

A plurality of logic cells for loading integrated circuits, stated in Japanese Published Unexamined Application bulletin No. 6-21263, are connected to power supply wiring VDD and power supply wiring GND and are installed on integrated circuits. The area between logic cells is, according to the logic connection information, the forming area of metal wiring for connection.

Crosstalk noise between wirings and simultaneous-switching noise of transistors constantly cause voltage variation in voltage of power supply wiring on the integrated circuit. This voltage variation causes slowdown in operation speed of transistors, mechanical errors, and so on. Given this fact, in order to control the voltage variation, technique installing the decoupling capacitor in the metal area between power supply wirings is disclosed in Japanese Published Unexamined Application bulletin No. 2001-185624. According to this technique, temporal voltage variation caused by noise etc. can be controlled by electric charges stored in the capacitor unit.

For the purpose as described above, for the capacitors used on integrated circuits, in the conventional manner, transistor component itself was used as a capacitor by utilizing the thin and high dielectric constant material, or the gate oxide of the transistor, for example. For those conventional capacitors used on integrated circuits, a capacitor cell made up of the conventional capacitor, which has a gate unit and its underlying basal plate as electrodes, is arranged in the forming area of the metal wiring. FIG. 1 is a cross-sectional diagram of the capacitor of the related art, and FIG. 2 is a type of configuration of capacitor of the related art.

On the silicon wafer 58, polygate 51 and LIC (Local Interconnect) 56a and 56b, which is composed of materials such as tungsten, are arranged through gate oxide film 53 composed of dielectrics with dielectric constant el. LIC 56a and 56b are joined directly to the silicon wafer 58. Polygate 51 is connected to the gate of the transistor and LIC 56a and 56b are respectively connected to either the source or the drain. Diffusion areas 57a and 57b are formed in the contact points of LIC 56a and 56b on the silicon wafer 58.

The capacitor described in FIG. 1 and FIG. 2 has polygate 51 and its underlying silicon wafer 58 as electrodes, is composed of gate oxide film 53 with dielectric constant ε1, and, by capacitor unit 59, ensures necessary capacitance C1 of the capacitor to control the voltage variation.

The capacitor 50 utilizing the gate oxide film of the transistor as described in FIG. 1 and FIG. 2 has a problem that increase in the area of the polygate 51 used as an electrode in order to increase the capacitance C1 of capacitor 59 also increases the resistance of the polygate 51 on the electrode, and reduces the capacitance C1 of capacitor 59 which is effective to high frequency noise.

In addition, gate oxide film of transistors is getting thinner by the high-integration and high-density technology on the integrated circuit in recent years. As the gate oxide film gets thin, capacitance C1 of the capacitor increases, and leakage current also increases. And it causes problems such as increase in the power consumption of the chip itself, which consists of capacitor, and transistor that cannot serve as a capacitor.

### SUMMARY OF THE INVENTION

The purpose of the present invention is to provide the capacitor that reduces power consumption as well as retains the same capacitance as that of conventional capacitors and reduces leakage current from the capacitor.

A MIS capacitor according to the present invention comprising: silicon wafer that is with diffusion area formed in a predetermined area of one side and that comprises the lower electrode of the capacitor; a first metal layer that is connected to a first power supply wiring and that comprises the upper electrode of the capacitor; a second metal layer connected to a second power supply wiring and formed on the surface of the diffusion area of the silicon wafer; and an oxide film placed between the first metal layer and the surface of the diffusion area on the silicon wafer.

The upper electrode of the capacitor is composed of a first metal layer. For this reason, the sheet resistance of the electrode units of the capacitor can be decreased. The oxide film placed between the first metal layer, which consists of the upper electrode, and the silicon wafer is made into the desired thickness. Therefore, it is possible for the present MIS capacitor to retain the same capacitance as the conventional capacitor without changing the space for the device.

The first metal layer can be connected to a first power supply wiring through a first wiring metal which is electrically conductive, and a second metal layer can be connected through a second power supply wiring through a second wiring metal, which is also electrically conductive. In addition, the first power supply wiring can be connected to a gate of the transistor, and the second power supply wiring can be connected to either a source or a drain of the transistor.

A first and second metal layer may be local interconnect. Tungsten for example, is preferred. Also, field oxide film is preferred for oxide film.

A MIS capacitor production method to the present invention, comprising: forming diffusion area on a predetermined area of a silicon wafer; forming a insulator layer on the silicon wafer; making a first hole, a second hole, and a third hole on the insulator layer, each of the holes reaches the diffusion area on the silicon wafer through the insulator layer; forming oxide film with a predetermined thickness at the bottom of the first hole; and filling the first hole, the second hole, and the third hole with metal.

According to the present invention, because the upper electrode of the capacitor is composed of metal, the sheet resistance of a capacitor electrode unit can be lowered. As a result, the increase of capacitance in the high frequency area becomes possible. Because a dielectric used as oxide film consisting of a MIS capacitor and thickness of the oxide film are established/set freely, capacitance of the MIS capacitor can be flexibly set. And using oxide film material with higher dielectric constant allows the capacitor to maintain the capacitance, to reduce leakage current in capacitor and to control the power consumption. Also, because there is no need to change the area of electrode that consists of MIS capacitor, more effective control of high frequency noise is possible without changing the occupying area of the capacitor.

### BRIEF DESCRIPTION OF THE DRAWINGS

FIG. 1 is a cross-sectional diagram of the conventional capacitor;

FIG. 2 exemplifies a configuration of the conventional capacitor;

FIG. 3 shows a cross-sectional diagram of MIS capacitor;

FIG. 4 is an overhead view of MIS capacitor;

FIG. 5 explains the production process of MIS capacitor;

FIG. 6 is a cross-sectional diagram of the other example of MIS capacitor;

FIG. 7 explains the characteristics of capacitor based on the structure of MIS capacitor;

FIG. 8 is a graph in approximation showing the relation between the absolute value of impedance (electric resistance) of the capacitor and the noise frequency; and

FIG. 9 is an example of MIS capacitor arrangement on an integrated circuit.

### DESCRIPTION OF THE PREFERRED EMBODIMENTS

The detailed explanation of the preferred embodiments with reference to the drawings is given below.

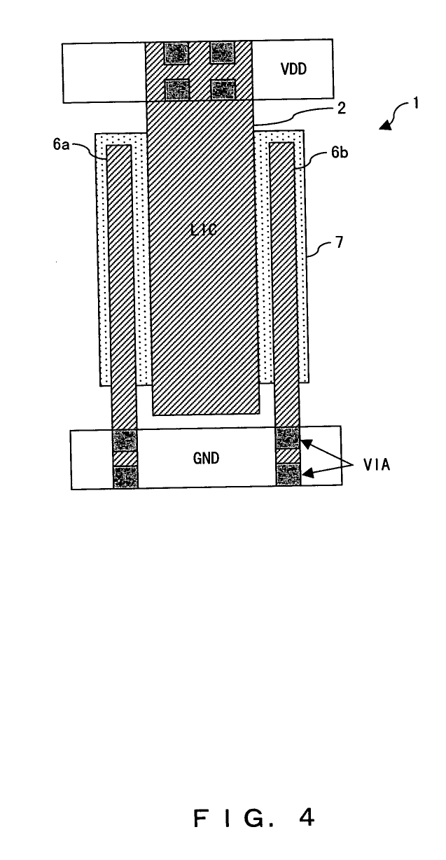

FIG. 3 is a cross-sectional diagram of the present embodiment, MIS (Metal-Insulator-Silicon) capacitor. FIG. 4 represents an overhead view of the present embodiment, MIS (Metal-Insulator-Silicon) capacitor. There are Local Interconnect (LIC) layer 2 constructed with material such as tungsten, and LIC layers 6a and 6b directly joined on silicon wafer B. LIC layer 2 is joined on the silicon wafer 8 through oxide film such as field oxide film 3. Wiring layer 4, which is connected to power supply wiring VDD, is set up on first via layer, which is mounted on LIC layer 2. Wiring layer 5a and 5b connected to power supply wiring GND are set up on first via layers, which are mounted on LIC layer 6a and 6b respectively. Diffusion area 7 is formed on the surface of silicon wafer 8, joined to field oxide film 3, which is between LIC layer 2 and silicon wafer 8, LIC layer 6a and LIC layer 6b.

In this present embodiment, field oxide film with dielectric constant of ε is used as an example of oxide film serving as capacitance film located between silicon wafer 8 and LIC layer 2 that is connected to VDD 4 through first via layer. Field oxide film 3 makes up capacitor 10 as well as LIC layer 2 that comprise the upper electrode and silicon wafer that comprises lower electrode. The dielectric constant E of field oxide film 3 can be greater than the dielectric constant ε1 of gate oxide.

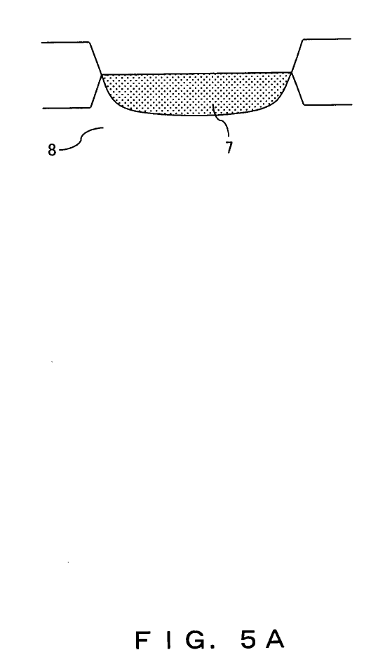

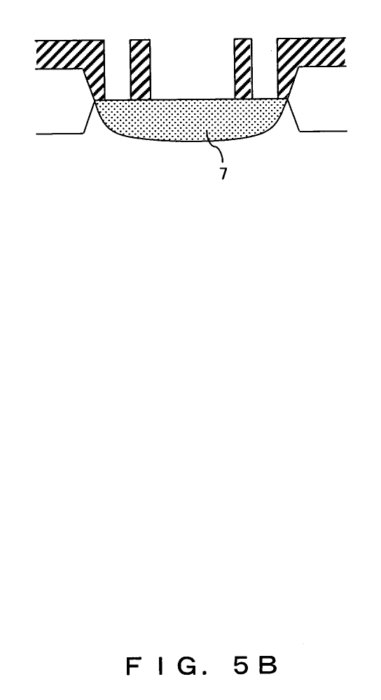

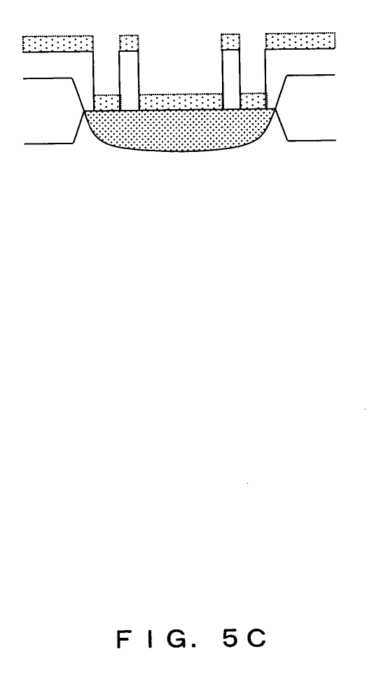

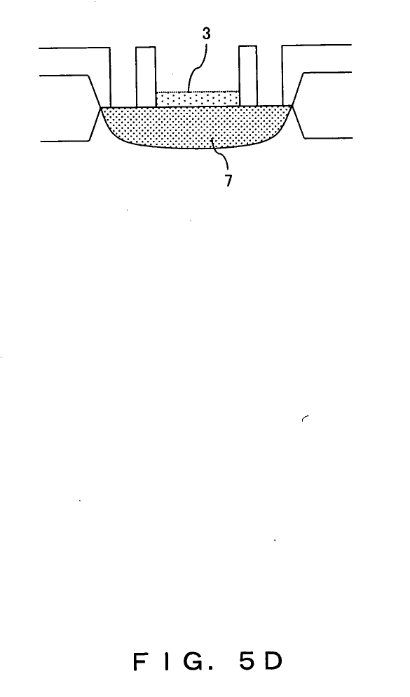

LIC layer 2 that is connected to power supply wiring VDD and comprises upper electrode of capacitor 10 is composed of metal with electric conductivity. As a result, diffusion area is formed in the area where silicon wafer 8 contacts with field oxide film 3. From FIG. 5A to FIG. 5E shows the production process of the present embodiment of MIS (Metal-Insulator-Silicon) capacitor. The detailed explanation of the production process of MIS capacitor 1 with reference to the drawings is given below.

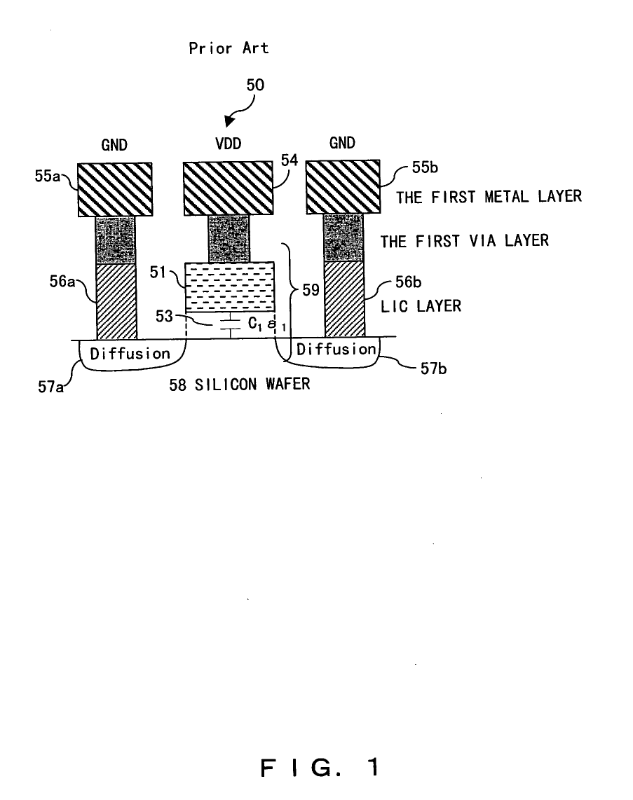

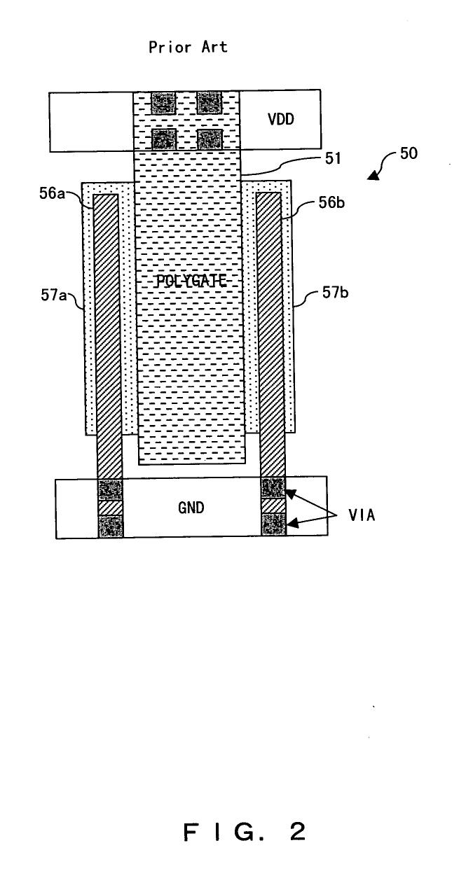

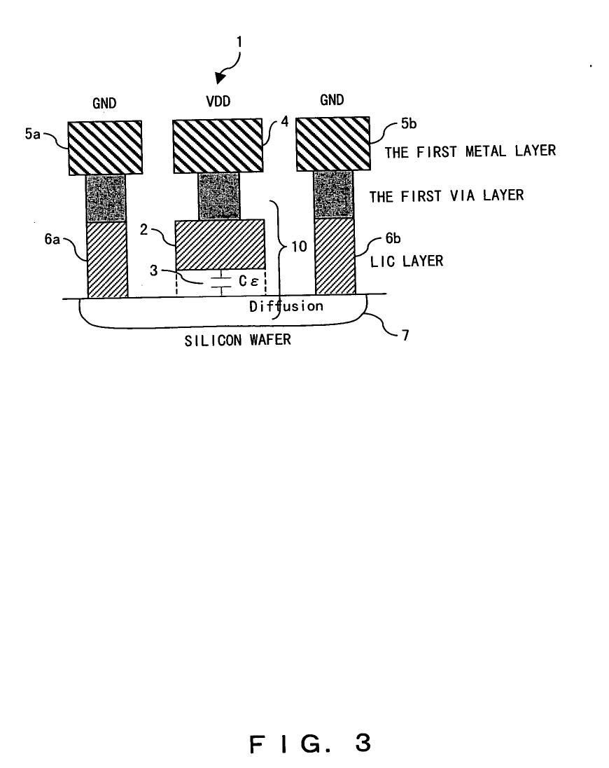

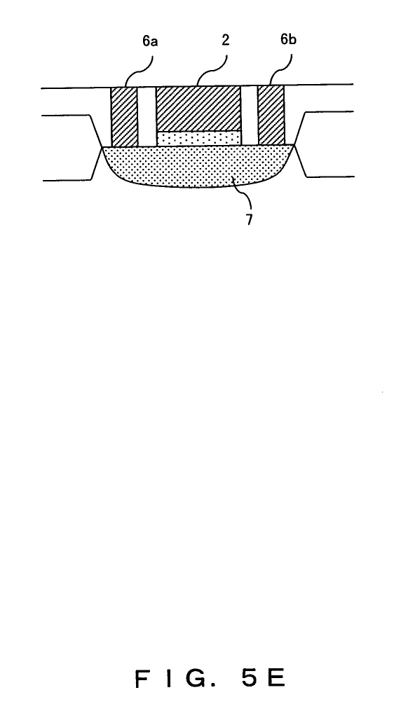

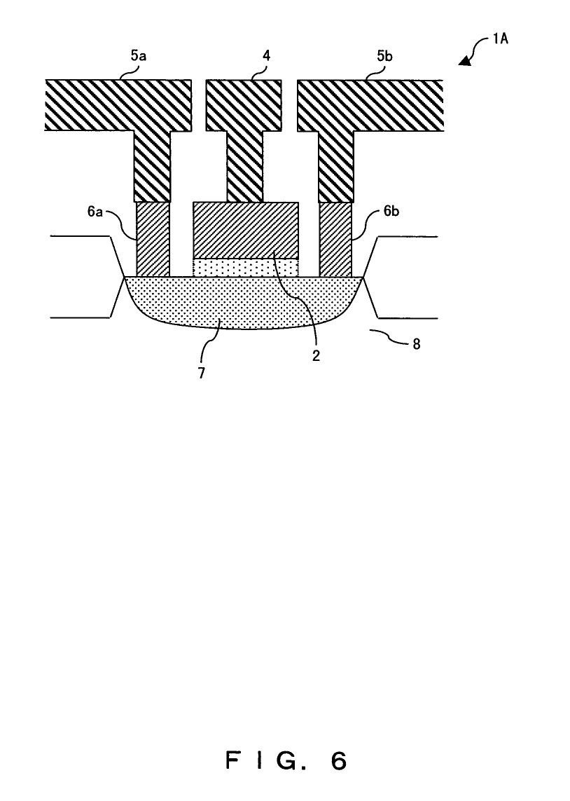

First, as it is showned in FIG. 5A, diffusion area 7 is formed on the silicon wafer 8. Compared with diffusion area formed on the conventional capacitor indicated in FIG. 1, the present embodiment of MIS capacitor 1 has diffusion area 7 formed in the area underneath the capacitor 10. Next, insulator layer is formed on the whole surface of silicon wafer 8 with diffusion area 7 formed, and then holes are made in the points where wiring metals and an electrode are to be formed in the insulator layer. FIG. 5B describes the holes made at the points where wiring metals and the electrode are formed in the insulator layer. The insulator where the holes are made of is represented in the area with diagonal lines in FIG. 5B. After making the holes, as it is showned in FIG. 5C, oxide film is formed on the surface of the insulator. The oxide film is removed by etching except for the part where the electrode is to be formed, as it is showned in FIG. 5D. FIG. 5E is a diagram showing the electrode formed with metal. LIC layer is formed by filling the metal in holes of each electrode, and the metal is brought into contact with the diffusion area of the silicon wafer. Lastly, making metal for wiring completes the whole production process of MIS capacitor 1 showned in FIG. 3. In FIG. 3, via layers are formed between LIC layer 2, 6a and 6b and wiring layer 4, 5a and 5b respectively, but the embodiment is not limited to the above described one. As the other example of the present embodiment of MIS (Metal-Insulator-Silicon) capacitor, for example, via layer can be an embedded via with stack architecture and wiring can be placed directly to this part. FIG. 6 is a cross-sectional diagram of such MIS capacitor 1.

According to the above-described production method of MIS capacitor, dielectric is formed in predetermined thickness with predetermined dielectric constant as oxide film between electrodes. And this method can give the desired capacitance to capacitor 10. By utilizing this result, the leakage current, which is peculiar to transistors, can be reduced to trivial level. Generally, the following relation is established between leakage current Ig at the gate and thickness of gate oxide Tₒₓ.
I_{g}∝1/Tₒₓ

As the formula above indicates, value of leakage current is inversely proportional to the thickness of oxide film of capacitor 10. To be more specific, making the thickness of gate oxide by 20 Å thicker can eliminate one figure from the value of leakage current I_{g}. In the present embodiment of MIS (Metal-Insulator-Silicon) capacitor, field oxide film makes up capacitor 10 instead of using gate oxide film of transistors. This field oxide film can be manipulated to have predetermined thickness and dielectric constant. In the case that dielectric (oxide film) with dielectric constant ε is used, the relation between the thickness of oxide film (distance between electrodes) T and capacitance of capacitor 10 with electrode area S are expressed as following.
C=ε*S/T (1)

In the present embodiment of MIS (Metal-Insulator-Silicon) capacitor, dielectric constant E and thickness T can be set freely even though the electrode area S remains the same. By utilizing this, the leakage current can be reduced. This reduction of the leakage current puts the power consumption of capacitor 10 under control.

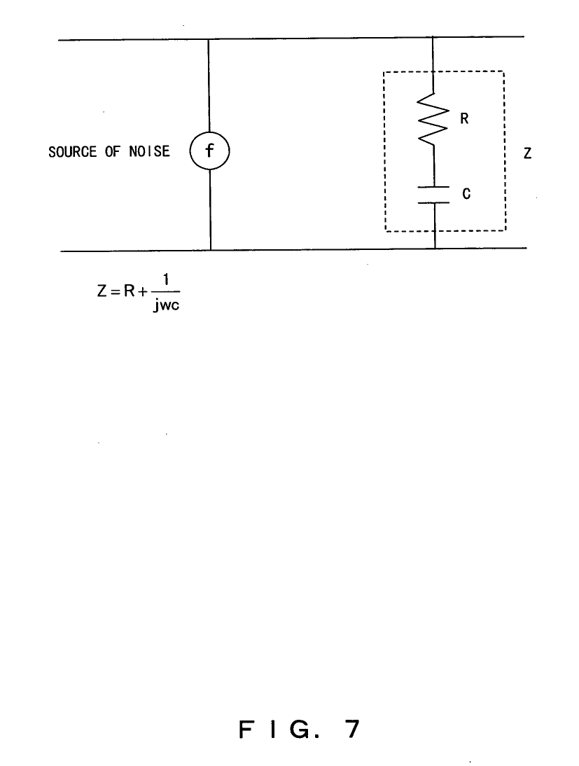

FIG. 7 explains the specific characteristics of capacitor 10 based on the structure of the present embodiment of MIS capacitor. Assume that frequency of the noise source is f, capacitance of capacitor 10 is C, regarding LIC layer comprising the upper electrode of capacitor 10, sheet resistance is R, and impedance of capacitor 10 is Z. Additionally, capacitance C is generated in the area where LIC layer 2 and diffusion area overlap each other in FIG. 3 and FIG. 4.

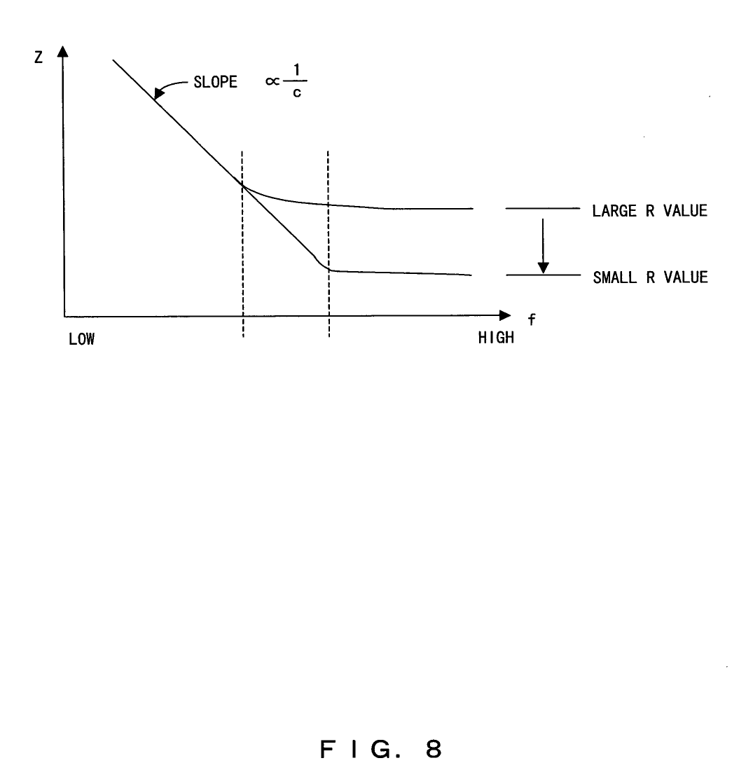

The impedance Z in FIG. 7 is expressed as the following.
Z=R+1/jωc (2)
In the above expression, j represents imaginary number. FIG. 8 is a graph in approximation showing the relation, represented by the expression (2), between absolute value of impedance Z and noise frequency f in capacitor. In the area of high frequency of noise, that is the area with large f value, the absolute value of impedance Z is mainly affected by the resistance R rather than by capacitance of capacitor 10.

Here, assume R=0.3 [Ω/□] for the sheet resistance R of the present embodiment of capacitor 10. On the other hand, assume Rₚ=10 [Ω/□] for the sheet resistance Rₚ in polygate layer of the present embodiment of capacitor 10. That is to say, compared with the capacitor utilizing polygate in transistor as in the conventional manner, resistance at upper electrode of the present embodiment of capacitor is 0.3/10=0.03 times, or is lowered by thirtieth part. By reducing the upper electrode resistance by thirtieth part, the influence of sheet resistance R in high frequency range become small, and capacitance C of capacitor 10 is affected mainly by high frequency noise. In other words, reduction of the sheet resistance can make capacitor function more effectively in the noise in high-frequency range without changing the capacitance of capacitor.

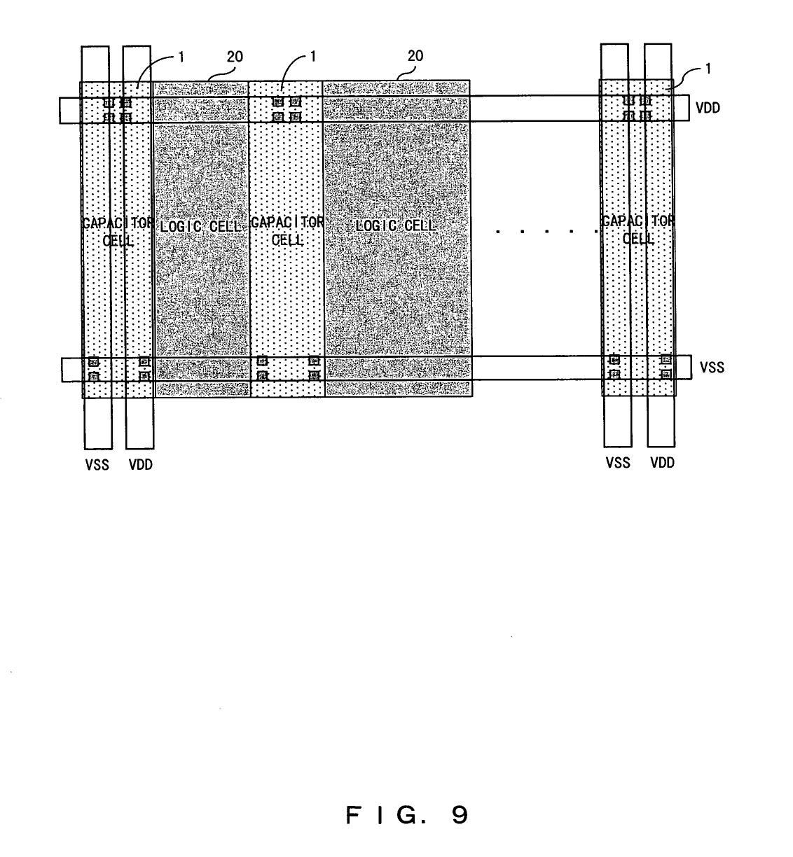

FIG. 9 is an example of the configuration of the present embodiment of MIS capacitor on the integrated circuit. In FIG. 9, capacitor cell 1 and logic cell 20 are arranged on the integrated circuit 30, according to the design. Logic cell 20 is arranged following the logic connection information of the integrated circuit. VDD wirings and VSS (GND) wirings arranged in the right and left directions of the diagram are power supply wiring of the first layer, and VDD wiring and VSS (GND) wiring arranged in above and below directions of the diagram are power supply wiring of the second layer in FIG. 9. The present embodiment of capacitor cell 1 is arranged on the integrated circuit in order to control the voltage variation caused by crosstalk noise between wirings and simultaneous switching etc.

Incidentally, in regard to the present embodiment of MIS capacitor, that is capacitor cell 1 in FIG. 9, as it is represented in the expression (1), its capacitance is determined by the dielectric constant ε of the dielectric using field oxide film and by the thickness of the oxide film T, and there is no need to change the electrode area S. That is, compared with the conventional design, the change in space for the present embodiment of MIS capacitor is not needed, and therefore, capacitor cell 1 can be introduced without changing the design of the conventional integrated circuit.

As it is explained above, in the present embodiment of MIS capacitor, because the upper electrode is composed of metal, the sheet resistance in the upper electrode of the capacitor can be lowered. As a result, the increase of capacitance in the high frequency area becomes possible. Also, because dielectric used as oxide film comprising MIS capacitor and thickness of the oxide film can be set freely, capacitance of MIS capacitor can be set flexibly. And using oxide film material with higher dielectric constant allows the capacitor to maintain the capacitance, to reduce leakage current in capacitor and to control the power consumption. In addition, because there is no need to change the area of electrode that comprises MIS capacitor, more effective control of high frequency noise is possible without changing the occupied area for the capacitor.

What is claimed is:

1. A MIS capacitor comprising:
silicon wafer that is with diffusion area formed in a predetermined area of one side and that comprises the lower electrode of the capacitor;
a first metal layer that is connected to a first power supply wiring and that comprises the upper electrode of the capacitor;
a second metal layer connected to a second power supply wiring and formed on the surface of the diffusion area of the silicon wafer; and
an oxide film placed between the first metal layer and the surface of the diffusion area on the silicon wafer.

2. The MIS capacitor according to claim 1, wherein
the first metal layer is connected to the first power supply wiring through a first wiring metal with electrical conductivity; and
the second metal layer is connected to the second power supply wiring through a second wiring metal with electrical conductivity.

3. The MIS capacitor according to claim 1, wherein
the first power supply wiring is connected to a gate of a transistor comprising a semiconductor device using the MIS capacitor, and the second power supply wiring is connected to either a source or a drain of a transistor.

4. The MIS capacitor according to claim 1, wherein
each of the first and second metal layer is local interconnect.

5. The MIS capacitor according to claim 1, wherein
each of the first and second metal layer is composed of tungsten.

6. The MIS capacitor according to claim 1, wherein
the oxide film is a field oxide film.

7. The MIS capacitor according to claim 1, wherein
said MIS capacitor is used as a noise-reducing capacitor cell in an integrated circuit.

8. A MIS capacitor production method, comprising:
forming diffusion area on a predetermined area of a silicon wafer;
forming a insulator layer on the silicon wafer;
making a first hole, a second hole, and a third hole on the insulator layer, each of the holes reaches the diffusion area on the silicon wafer through the insulator layer;
forming oxide film with a predetermined thickness at the bottom of the first hole; and
filling the first hole, the second hole, and the third hole with metal.
